(19) United States
(12) Patent Application Publication
(10) Pub. No.: US 2012/0032585 A1
(43) Pub. Date: Feb. 9, 2012

(54) LIGHT EMITTING ELEMENT

(75) Inventor: Daisuke Yamada, Yokohama-shi (JP)

(73) Assignee: CANON KABUSHIKI KAISHA, Tokyo (JP)

(21) Appl. No.: 13/177,817

(22) Filed: Jul. 7, 2011

(30) Foreign Application Priority Data
Aug. 6, 2010 (JP) 2010-177080

(51) Int. Cl. H01J 1/62

(52) U.S. Cl. 313/509

(57) ABSTRACT

Provided is a light emitting element capable of reducing external light reflectance while maintaining high light extraction efficiency, having a structure including a back surface member provided on a side of an emission layer opposite to a light extraction side, the back surface member including in order from the emission side: a dielectric layer having a smaller effective refractive index than that of the emission layer; and a metal fine patterned layer interacting with light entering a metal fine patterned layer to change level of reflectance, and back surface member reflectance with respect to light with an incident angle larger than the critical angle determined by conditions for total reflection at an interface between the emission and the dielectric layer is higher than back surface member reflectance with respect to light with an incident angle smaller than the critical angle.

### BACKGROUND OF THE INVENTION

1. Field of the Invention

The present invention relates to a light emitting element, and more particularly, to a light emitting element which utilizes plasmon resonance to achieve high photopic contrast.

2. Description of the Related Art

In recent years, the development of light emitting elements using fluorescent substances or the like is advanced for surface-conduction electron-emitter displays, organic electroluminescence (EL) displays, light emitting diode (LED) displays, and other types of displays. Of those displays, the light emitting element mounted in the surface-conduction electron-emitter display has a structure in which electrons emitted from an electron source are used as an excitation source to excite an emission layer formed of a phosphor or the like so as to emit light, and the light is extracted to the outside. Further, the light emitting element mounted in the organic EL display or the LED display has a structure in which a current as an excitation source is injected to an emission layer so as to emit light, and the light is extracted to the outside.

In those types of light emitting elements, in order to increase luminance of the light emitting element, an attempt has been made to extract the light emitted from the emission layer efficiently to the outside (i.e. to increase light extraction efficiency). As a technology for increasing the light extraction efficiency, U.S. Pat. No. 6,476,550 proposes the organic EL element structured as follows. The organic EL element employs a technology in which a metal film (electrode) is provided on a back surface member so that light which is emitted to the side opposite to the light extraction side (i.e., back surface member side) may be reflected to the light extraction side to increase the light extraction efficiency.

The displays using such light emitting elements are required to have high photopic contrast for improving visibility under well-lit conditions. In order to increase the photopic contrast, the light emitting element needs to have high light extraction efficiency and low external light reflectance. Note that, the external light reflectance means at what percentage of light entering the light emitting element from the outside, such as fluorescent light and sunlight, is reflected inside the light emitting element to be emitted to the outside again.

However, in the structure in which the metal electrode is provided on the back surface member described in U.S. Pat. No. 6,476,550, although the light extraction efficiency is increased, no consideration is given to the reflection of external light. Consequently, the light emitting element described in U.S. Pat. No. 6,476,550 has a problem in that the external light entering the light emitting element is strongly reflected at the electrode of the metal film of the back surface member and hence the external light reflectance is high and the photopic contrast is low.

### SUMMARY OF THE INVENTION

The present invention has been made in view of the above-mentioned problem, and it is therefore an object of the present invention to provide a light emitting element which is capable of reducing external light reflectance while maintaining high light extraction efficiency.

The present invention provides a light emitting element having a structure in which an emission layer is excited to emit light by an excitation source and the light is extracted from the emission layer to an outside, the light emitting element including a back surface member, which is provided on a side of the emission layer opposite to a light extraction side, in which the back surface member includes in order from the emission layer side: a dielectric layer which has a smaller effective refractive index than an effective refractive index of the emission layer; and a metal fine patterned layer which interacts with light which is emitted from the emission layer to enter the metal fine patterned layer via the dielectric layer, to thereby change level of reflectance according to a wavelength of the light, and in which, when a critical angle determined by conditions for total reflection at an interface between the emission layer and the dielectric layer is expressed by the following expression (1), a back surface member reflectance with respect to light with an incident angle larger than the critical angle is higher than a back surface member reflectance with respect to light with an incident angle smaller than the critical angle.

$$θ c = arc sin [ \frac{N 2}{N 1} ] \qquad ( Expression 1 )$$

where the effective refractive index means an average refractive index in each of the emission layer and the dielectric layer, θc represents the critical angle, N1 represents the effective refractive index of the emission layer, and N2 represents the effective refractive index of the dielectric layer.

According to the present invention, it is possible to achieve a light emitting element which is capable of reducing external light reflectance while maintaining high light extraction efficiency.

Further features of the present invention will become apparent from the following description of exemplary embodiments with reference to the attached drawings.

### BRIEF DESCRIPTION OF THE DRAWINGS

FIG. 1 is a schematic cross-sectional diagram illustrating the structure of a light emitting element used for a surface-conduction electron-emitter display according to Embodiment 1 of the present invention.

FIGS. 2A and 2B are graphs illustrating reflectance of light entering a back surface member from an emission layer (i.e., back surface member reflectance) in the light emitting element according to Embodiment 1 of the present invention.

FIG. 3 is a diagram illustrating incident angle dependence of the back surface member reflectance in the light emitting element according to Embodiment 1 of the present invention.

FIG. 4 is a schematic cross-sectional diagram illustrating the structure of a light emitting element used for a surface-conduction electron-emitter display according to Embodiment 2 of the present invention.

FIGS. 5A, 5B, 5C and 5D are diagrams illustrating light emitted from an emission layer of the light emitting element according to Embodiment 2 of the present invention.

FIGS. 6A, 6B, 6C and 6D are diagrams illustrating the light emitted from the emission layer of the light emitting element according to Embodiment 2 of the present invention.

FIG. 7 is a schematic cross-sectional diagram illustrating the structure of a light emitting element used for an organic electroluminescence (EL) display according to Embodiment 3 of the present invention.

FIG. 8 is a schematic cross-sectional diagram illustrating the structure of a light emitting element used for an LED display according to Embodiment 4 of the present invention.

FIG. 9 is a diagram illustrating a structure example of a metal fine patterned layer in a light emitting element according to Example 1 of the present invention.

FIG. 10A is a graph illustrating back surface member reflectance corresponding to an incident angle in one light emitting element according to Example 1 of the present invention.

FIG. 10B is a graph illustrating back surface member reflectance corresponding to an emission wavelength in the one light emitting element according to Example 1 of the present invention.

FIG. 11 is a graph illustrating a state of back surface member reflectance corresponding to an incident angle in another light emitting element according to Example 1 of the present invention.

FIG. 12 is a diagram illustrating the structure of a metal fine patterned layer in a light emitting element according to Example 3 of the present invention.

FIG. 13A is a graph illustrating reflectance of light which is emitted from an emission layer to the side opposite to a light extraction side and enters a dielectric layer and a metal fine patterned layer in the light emitting element according to Example 3 of the present invention.

FIG. 13B is a graph illustrating reflectance of light which is emitted from an emission layer to the side opposite to a light extraction side and enters a dielectric layer and a metal fine patterned layer in a light emitting element using silver as an electrode according to Example 3 of the present invention.

FIGS. 14A, 14B, 14C, 14D, 14E, 14F and 14G are diagrams illustrating a manufacturing process of each numerical example according to Example 4 of the present invention.

### DESCRIPTION OF THE EMBODIMENTS

Referring to the accompanying drawings, a light emitting element according to the present invention is described below by way of Embodiments and Examples. Note that, throughout the drawings used for illustrating Embodiments and Examples, the same reference symbols denote portions having the same functions, and repetitive description thereof is omitted.

### Embodiment 1

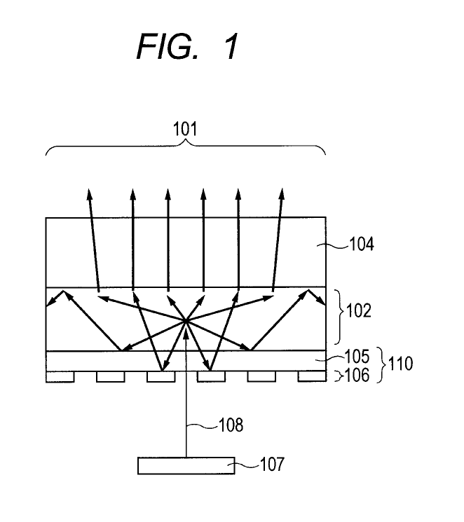

As Embodiment 1 of the present invention, the structure of a light emitting element used for a surface-conduction electron-emitter display is described with reference to FIG. 1. A light emitting element 101 of this embodiment includes a face plate 104 on a light extraction side of an emission layer 102. The light emitting element 101 further includes a back surface member 110 on the side of the emission layer 102 opposite to the light extraction side. The back surface member 110 is constituted such that a dielectric layer 105 and a metal fine patterned layer 106 are provided in the stated order from the emission layer 102 side.

Then, by applying an external voltage to the metal fine patterned layer 106, electrons 108 as an excitation source which are emitted from an electron source 107 are efficiently guided to the emission layer 102 and radiated to the emission layer 102. The irradiated emission layer 102 emits light of a color corresponding to each pixel of the display. The emitted light is extracted to the outside via the face plate 104. Here, the dielectric layer 105 is structured to have a smaller effective refractive index than an effective refractive index of the emission layer 102 so that light propagating inside the emission layer 102 may be totally reflected at the interface between the emission layer 102 and the dielectric layer 105 at a given angle or larger.

In this case, when the critical angle determined by conditions for total reflection at the interface between the emission layer and the dielectric layer is expressed by the following expression (1), light entering the dielectric layer at the critical angle or larger is totally reflected.

$$θ c = arc sin [ \frac{N 2}{N 1} ] \qquad ( Expression 1 )$$

where the effective refractive index means an average refractive index in each of the emission layer and the dielectric layer, θc represents the critical angle, N1 represents the effective refractive index of the emission layer, and N2 represents the effective refractive index of the dielectric layer.

Of the light propagating inside the emission layer 102, light entering the back surface member 110 at an angle smaller than the critical angle θc is transmitted through the dielectric layer 105 and reflected at the metal fine patterned layer 106 by interaction with the metal fine patterned layer 106. In this case, the metal fine patterned layer 106 interacts with light which is emitted from the emission layer to enter the metal fine patterned layer via the dielectric layer, to thereby change the level of reflectance according to a wavelength of the light. For example, the metal fine patterned layer 106 changes the level of reflectance by interaction according to the wavelength, so as to have high reflectance with respect to the center wavelength of an emission band of light emitted from the emission layer and to have lower reflectance than that of a metal layer with respect to at least one wavelength other than the center wavelength.

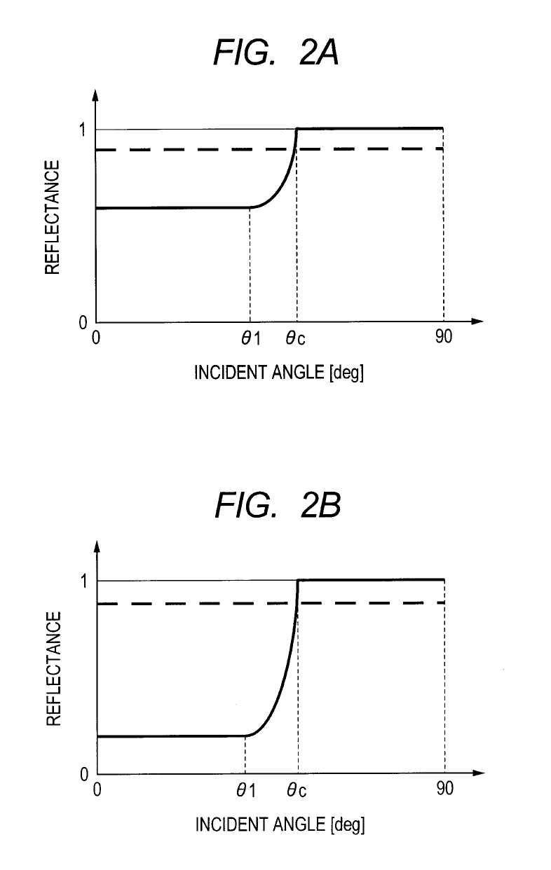

As an example, reflectance of light entering the back surface member 110 from the emission layer 102 (i.e., back surface member reflectance) is described with reference to FIGS. 2A and 2B. FIG. 2A illustrates reflectance with respect to an emission wavelength of the emission layer 102. FIG. 2B illustrates back surface member reflectance with respect to a wavelength different from the center wavelength of an emission band, more preferably a wavelength different from the emission band. Note that, the emission band as used herein refers to a wavelength region in which the ratio of intensity at the center wavelength of light emitted from the emission layer is larger than the square of 1/e. Note that, for reference, FIGS. 2A and 2B illustrate, by the broken line, back surface member reflectance which is measured in a structure using a metal film as the back surface member.

Such structure enables the use of incident angle dependence of the back surface member reflectance and the use of wavelength selectivity of the back surface member reflectance for light having a small incident angle, thereby being capable of lowering external light reflectance as compared to the structure using a metal film.

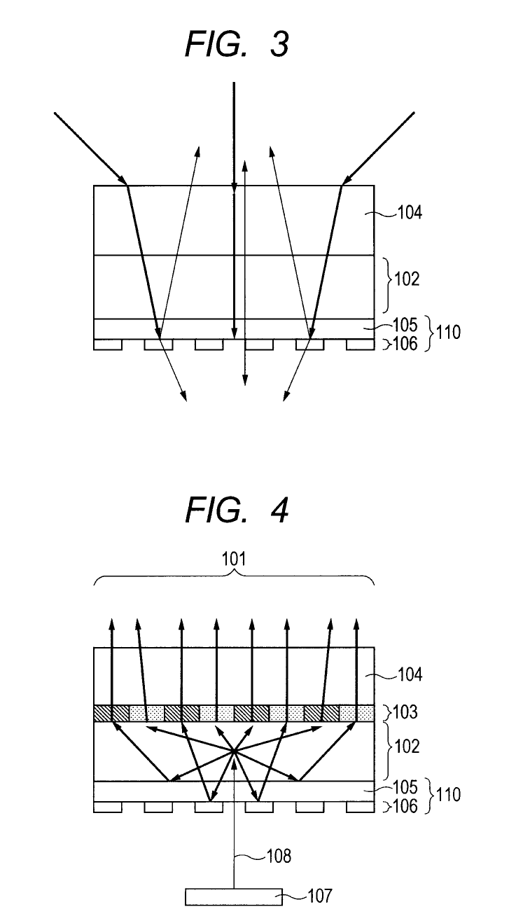

The incident angle dependence of the back surface member reflectance is described with reference to FIG. 3. Referring to FIG. 3, external light propagates, via the face plate 104, inside the emission layer 102 at an angle smaller than a maximum refraction angle θ1 and enters the back surface member 110, which is formed of the dielectric layer 105 and the metal fine patterned layer 106. Note that, the maximum refraction angle θ1 is determined by Snell's law for air having a refractive index of 1.0 and the effective refractive index N1 of the emission layer having, and is expressed by the following expression (2).

$$θ 1 = arc sin [ \frac{1}{N 1} ] \qquad ( Expression 2 )$$

In this case, the refractive index of the dielectric layer 105 is larger than the refractive index of air, and hence the maximum refraction angle θ1 is smaller than the critical angle θc. Accordingly, the external light propagating inside the emission layer 102 is reflected at the back surface member 110 in the range from 0 degrees to the maximum refraction angle θ1, according to the back surface member reflectance. If the back surface member reflectance is small, the percentage at which the external light is reflected again to the light extraction side is lowered, and the external light reflectance is thus lowered.

Next, the wavelength selectivity of the back surface member reflectance is described. External light entering the light emitting element contains light having multiple wavelengths (colors) rather than a specific wavelength (color). It is therefore important to reduce the external light reflectance with respect to multiple wavelengths.

In this embodiment, as illustrated in FIG. 2B, the back surface member reflectance in a small-incident angle region (range from 0 degrees to maximum refraction angle θ1) is set to be lower than the reflectance of the metal film with respect to a wavelength which is different from the emission band and does not contribute to light extraction efficiency. Therefore, the external light reflectance of the light emitting element 101 can be lowered as compared to the structure using a metal film.

Note that, this embodiment has exemplified only one wavelength as a wavelength different from an emission wavelength, but multiple wavelengths may also be applied.

The structure according to this embodiment is made as follows. First, light in a large-incident angle region in which the solid angle is large and the amount of emitted light is large (i.e., light entering at the critical angle θc or larger) is allowed to be totally reflected, to thereby obtain high back surface member reflectance of, for example, 100%. Subsequently, light entering the back surface member at an angle smaller than the critical angle θc is also allowed to interact with the metal fine patterned layer 106, to thereby obtain high reflectance with respect to an emission wavelength. As a result of the structure, high light extraction efficiency comparable to that in the structure using a metal film can be obtained.

As described above, in this embodiment, the dielectric layer and the metal fine patterned layer are provided on the side of the emission layer opposite to the light extraction side. Using the interaction with light which is emitted from the emission layer to enter the metal fine patterned layer via the dielectric layer, the back surface member reflectance is controlled for each incident angle and wavelength. In other words, the back surface member reflectance is controlled to be low with respect to light entering at a small incident angle other than an emission band and high with respect to light entering at a large incident angle of the emission band.

With this structure, a light emitting element having low external light reflectance while maintaining high light extraction efficiency can be obtained.

The metal fine patterned layer 106 can be constituted by regularly metal structures with apertures on the side of the dielectric layer opposite to the light extraction side. In this case, the metal fine patterned layer and incident light are interacted with each other so as to obtain back surface member reflectance which is high when the incident light causes plasmon resonance and low when the incident light causes no plasmon resonance. Therefore, desired back surface member reflectance can be obtained by forming the metal fine patterned layer so that plasmon resonance may occur with light at the center wavelength of an emission band while no plasmon resonance may occur with light at a wavelength different from the center wavelength of the emission band.

Further, the metal fine patterned layer 106 can be constituted by regularly providing apertures in a metal layer on the side of the dielectric layer opposite to the light extraction side. In this case, the metal fine patterned layer and incident light are interacted with each other so as to obtain back surface member reflectance which is low when the incident light causes plasmon resonance and high when the incident light causes no plasmon resonance. Therefore, desired back surface member reflectance can be obtained by forming the metal fine patterned layer so that no plasmon resonance may occur with light at the center wavelength of an emission band while plasmon resonance may occur with light at a wavelength different from the center wavelength of the emission band. Note that, instead of using resonance obtained by the metal fine patterned layer in which the structures are regularly arranged, localized resonance can also be used to impart desired back surface member reflection characteristics.

However, the structure in which the structures are regularly arranged in a plane can be manufactured over a large area more easily by a manufacturing method described later.

The metal fine patterned layer can serve also as an electrode when applied with an external voltage. If an additional metal film is used as an electrode, external light reflectance is increased. It is therefore desired that the metal fine patterned layer serve as both a reflection function and an electrode.

It is desired that the dielectric layer 105 have a thickness larger than a value obtained by dividing a wavelength of light emitted from the emission layer by the effective refractive index of the dielectric layer. Light which is emitted from the emission layer at the critical angle θc or larger is totally reflected at the interface between the emission layer and the dielectric layer, and an evanescent wave is generated in the dielectric layer. When the evanescent wave is coupled to the metal fine patterned layer, the evanescent wave is absorbed or converted into transmission light, leading to an emission loss to the back surface member. It is therefore desired that the thickness of the dielectric layer be large enough to prevent the evanescent wave from easily coupling to the metal fine patterned layer.

When the dielectric layer is structured to have the thickness as described above, the thickness of the dielectric layer is larger than a penetration depth of the evanescent wave. Consequently, most of the evanescent wave generated by total light reflection is not coupled to the metal fine patterned layer. Therefore, high reflectance close to 100% can be obtained with respect to light entering at the critical angle or larger, to thereby suppress the emission loss to the back surface member and obtain high light extraction efficiency.

Further, in this embodiment, the light emitting element is of an electron excitation type, which uses electrons as an excitation source. In this case, in particular, high light extraction efficiency can be obtained without degrading excitation efficiency of the emission layer. In the light emitting element of the electron excitation type, if a metal film serving as an electrode is provided on the back surface member side in order to increase the light extraction efficiency, electrons are absorbed by the metal electrode. As a result, the excitation efficiency of the emission layer is degraded to lower luminance of the light emitting element. If the metal electrode is not used, alternatively, an emission loss in the back surface member becomes large because reflectance on the back surface member side is low. As a result, the light extraction efficiency is lowered. However, with the structure using the metal fine patterned layer 106, the area of metal can be reduced as compared to the structure using a metal film, and the thickness of the metal fine patterned layer can be reduced because plasmon resonance is utilized.

According to the structure of this embodiment, the metal fine patterned layer as described above is used, and hence desired back surface member reflectance can be obtained without significantly degrading the excitation efficiency.

### Embodiment 2

As Embodiment 2, an example of the structure of the light emitting element in a different form from Embodiment 1 is described with reference to FIG. 4. As illustrated in FIG. 4, the light emitting element of this embodiment includes a graded-index diffraction element 103 between the emission layer 102 and the face plate 104. Note that, the structure of Embodiment 2 is the same as the structure of Embodiment 1 except that the above-mentioned graded-index diffraction element 103 is provided, and hence repetitive description thereof is omitted. The graded-index diffraction element functions to diffract light which is otherwise totally reflected at the emission layer and the face plate, so as to extract the light to the outside. Note that, the graded-index diffraction element may be any type of graded-index diffraction elements, such as periodic diffraction gratings, quasiperiodic photonic crystals with high symmetry, and non-periodic diffraction gratings.

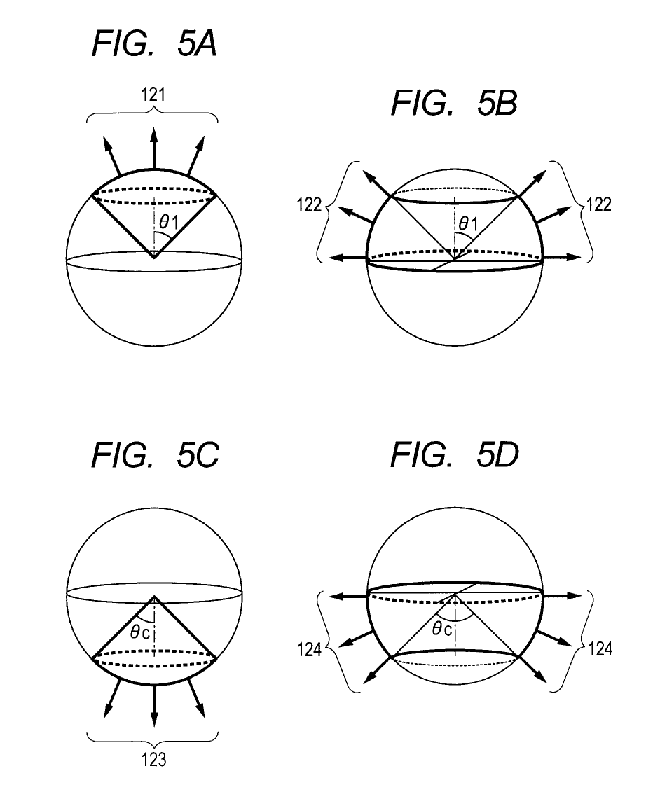

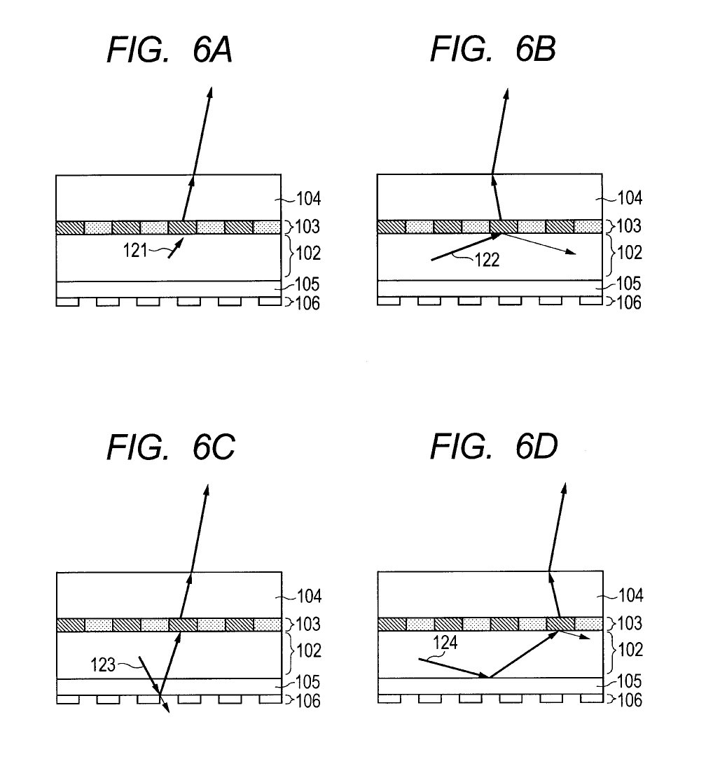

Next, an example of categorizing light emitted from the emission layer in the light emitting element of this embodiment into four is described with reference to FIGS. 5A to 5D and FIGS. 6A to 6D.

The light from the emission layer 102 is emitted in all directions. Accordingly, depending on the radiation direction, the light is categorized into four as illustrated in FIGS. 5A to 5D.

First light 121 is a component emitted to the light extraction side at an angle smaller than the maximum refraction angle θ1 (FIG. 5A).

Second light 122 is a component emitted to the light extraction side at an angle larger than the maximum refraction angle θ1 (FIG. 5B).

Third light 123 is a component emitted to the side opposite to the light extraction side at an angle smaller than the critical angle θc (FIG. 5C).

Fourth light 124 is a component emitted to the side opposite to the light extraction side at an angle larger than the critical angle θc (FIG. 5D).

Most of the first light 121 is transmitted through the face plate 104 to be extracted to the outside (FIG. 6A).

The second light 122 is confined into the emission layer 102 or the face plate 104, and is partially diffracted by the graded-index diffraction element 103 to be extracted to the outside (FIG. 6B).

The third light 123 is partially reflected to convert the beam direction to a direction toward the light extraction side as understood from FIG. 2A, and is extracted to the outside similarly to the first light 121 (FIG. 6C).

The fourth light 124 is totally reflected to convert the beam direction to a direction toward the light extraction side as understood from FIG. 2A, and is extracted to the outside similarly to the second light 122 (FIG. 6D).

The emission from the emission layer is isotropic radiation, which has a large amount of radiation of light entering at the critical angle θc or larger with a large solid angle. In view of this, in order to reduce a radiation loss to the back surface member to obtain high light extraction efficiency, reflectance in a region in which the light emitted from the emission layer enters at a large incident angle is set to be high, and the graded-index diffraction element is used, to thereby extract the light to the outside efficiently. In other words, by using the graded-index diffraction element, higher light extraction efficiency can be obtained.

Further, light entering at an angle smaller than the critical angle θc is also allowed to interact with the metal fine patterned layer 106 so that wavelength selectivity may be utilized for the light emitted from the emission layer. In this manner, high reflectance is provided and hence high light extraction efficiency can be obtained. This way, in this embodiment, the external light reflectance can be lowered while obtaining much higher light extraction efficiency.

Further, it is desired that the above-mentioned critical angle θc at the interface between the emission layer 102 and the dielectric layer 105 be smaller than 60 degrees. Light which is isotropically emitted from the emission layer has an amount of radiation half the whole amount of radiation at an angle range of from 60 degrees to 90 degrees. Accordingly, for extracting to the outside a sufficient amount of the light emitted to the back surface member, at least light entering at an angle of 60 degrees or larger is allowed to be totally reflected. In this manner, high light extraction efficiency can be obtained.

Further, it is desired that the difference between the critical angle θc and the maximum refraction angle θ1 be smaller than 30 degrees. The back surface member reflectance from 0 degrees to the maximum refraction angle θ1 largely contributes to the external light reflectance, whereas reflectance from the maximum refraction angle θ1 to 90 degrees does not contribute to the external light reflectance. Therefore, in consideration of light extraction efficiency, it is desired that the back surface member reflectance be high for light at an angle larger than the maximum refraction angle θ1. Light at the critical angle θc or larger is totally reflected to provide high reflectance. Therefore, setting the difference between the critical angle θc and the maximum refraction angle θ1 within 30 degrees increases a region in which light is totally reflected, thereby obtaining high light extraction efficiency.

### Embodiment 3

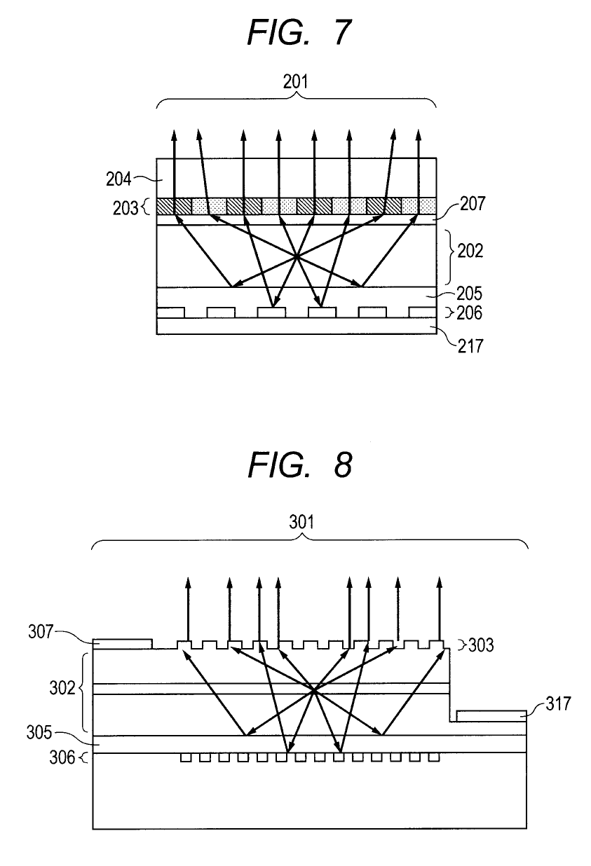

As Embodiment 3 of the present invention, the structure of a light emitting element used for an organic EL display is described with reference to FIG. 7. A light emitting element 201 of this embodiment includes, on a light extraction side of an emission layer 202, a transparent electrode 207, a graded-index diffraction element 203, and a face plate 204 in the stated order from the emission layer side. The light emitting element 201 further includes, on the side of the emission layer 202 opposite to the light extraction side, a dielectric layer 205, a metal fine patterned layer 206, and a transparent electrode 217 in the stated order from the emission layer side. A potential difference is applied between the transparent electrodes 207 and 217, and a current as an excitation source is injected to the emission layer 202 to excite the emission layer 202 so as to emit light of a color corresponding to each pixel. The emitted light is partially diffracted by the graded-index diffraction element 203 via the transparent electrode 207, and is transmitted through the face plate 204 to be extracted to the outside.

In this case, by using the dielectric layer 205 and the metal fine patterned layer 206, the back surface member reflectance from 0 degrees to the maximum refraction angle θ1 can be set to be lower than that in a structure using a metal film as an electrode, and wavelength selectivity can also be provided to lower the external light reflectance. Further, light in a large-incident angle region in which the solid angle is large and the amount of emitted light is large is allowed to be totally reflected so as to have high back surface member reflectance, to thereby obtain high light extraction efficiency.

According to this embodiment, with the structure described above, a light emitting element having low external light reflectance while maintaining high light extraction efficiency can be obtained.

### Embodiment 4

As Embodiment 4 of the present invention, the structure of a light emitting element used for an LED display is described with reference to FIG. 8. A light emitting element 301 of this embodiment includes a graded-index diffraction element 303 on a light extraction side of an emission layer 302. The light emitting element 301 further includes, on the side of the emission layer 302 opposite to the light extraction side, a dielectric layer 305 and a metal fine patterned layer 306 in the stated order from the emission layer side. Further, an electrode 307 is provided on the light extraction side of the emission layer 302 at one end of the upper surface of the emission layer 302 and adjacent to the graded-index diffraction element 303. An electrode 317 is disposed on the side of the emission layer 302 opposite to the light extraction side so as to be opposed to the electrode 307.

A potential difference is applied between the electrodes 307 and 317, and a current as an excitation source is injected to the emission layer 302 to excite the emission layer 302 so as to emit light of a color corresponding to each pixel. The emitted light is extracted to the outside via the graded-index diffraction element 303.

Note that, in the structure of this embodiment, the metal fine patterned layer 306 does not serve as an electrode, and hence an external voltage is not applied thereto. Further, the emission layer 302 is formed of multiple layers including an active layer.

In this case, by using the dielectric layer 305 and the metal fine patterned layer 306, the back surface member reflectance from 0 degrees to the maximum refraction angle θ1 can be set to be lower than that in a structure using a metal film as an electrode, and wavelength selectivity can also be provided to lower the external light reflectance. Further, light in a large-incident angle region in which the solid angle is large and the amount of emitted light is large is allowed to be totally reflected so as to have high back surface member reflectance, to thereby obtain high light extraction efficiency.

According to this embodiment, with the structure described above, a light emitting element having low external light reflectance while maintaining high light extraction efficiency can be obtained.

### EXAMPLES

Hereinafter, Examples of the present invention are described.

### Example 1

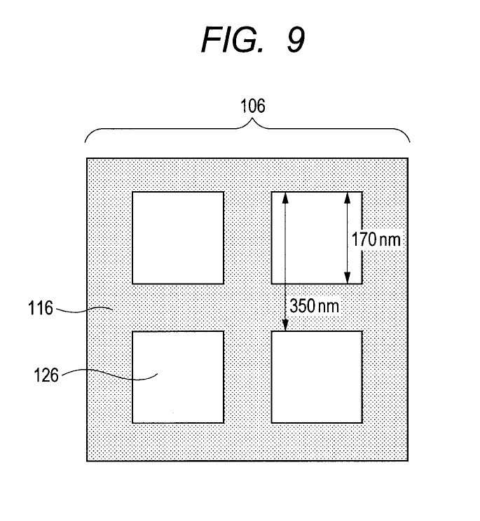

As Example 1, a numerical example of Embodiment 1 is described. The emission layer 102 is constituted of a phosphor which emits light at a wavelength of 550 nm when irradiated with electrons, and is formed to have an effective refractive index of 1.7. The dielectric layer 105 is constituted of MgF₂ (refractive index: 1.38) with a thickness of 650 nm. The metal fine patterned layer 106 is such a structure as illustrated in FIG. 9 in which apertures 126 each of which is constituted of air and is 170 nm on a side, are arranged in a metal film 116 which is constituted of aluminum with a thickness of 30 nm, in a square lattice at a cycle of 350 nm.

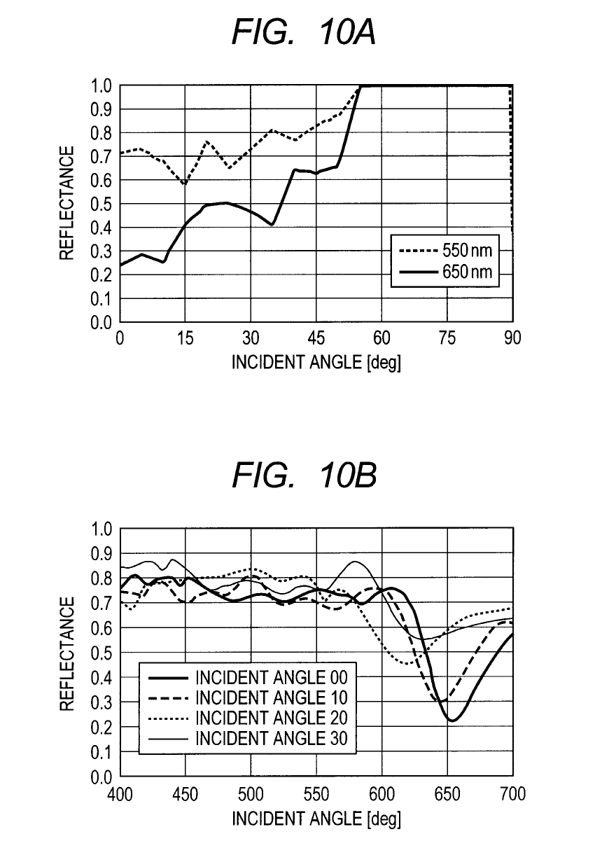

Back surface member reflectance corresponding to an incident angle in this case is illustrated in FIG. 10A, and back surface member reflectance corresponding to an emission wavelength is illustrated in FIG. 10B.

The average reflectance of light at a wavelength of 550 nm from an incident angle of 0 degrees to the maximum refraction angle θ1 (36 degrees) is 70%. The average reflectance of light at a wavelength of 650 nm from the incident angle of 0 degrees to the maximum refraction angle θ1 (36 degrees) is 39%. Further, the back surface member reflectance of light entering at the critical angle θc (54 degrees) or larger is 100%. Subsequently, the percentage at which the light isotropically emitted from the emission layer 102 is extracted to the outside of the light extraction side (i.e., light extraction efficiency) was calculated. The calculated light extraction efficiency was 17%.

Further, a dominant factor of the external light reflectance of the light emitting element is the back surface member reflectance of light emitted from the emission layer 102. Accordingly, the external light reflectance is approximately 70% and 39% for the wavelengths of 550 nm and 650 nm, respectively. Note that, in general, external light reflectance of a display is determined by the product of the percentage of the light emitting element (aperture ratio) and the external light reflectance of the light emitting element.

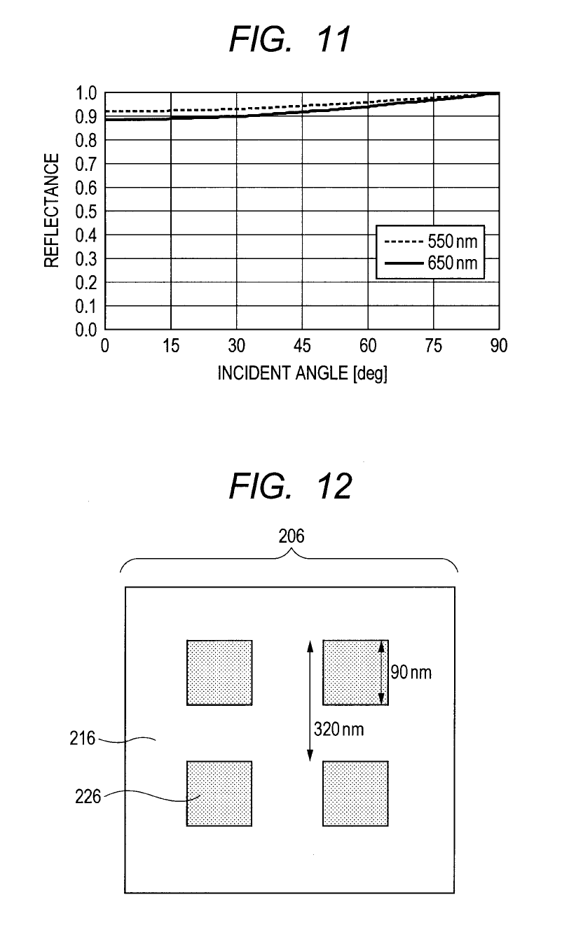

Next, light extraction efficiency and external light reflectance are calculated for a structure in which a metal film constituted of aluminum is formed on the side of the emission layer 102 opposite to the light extraction side. Note that, reflectance of light from the emission layer toward the back surface member is approximately 90% for all incident angles and both wavelengths (FIG. 11). In this case, while light extraction efficiency is 19%, external light reflectance is 93% and 89% for wavelengths of 550 nm and 650 nm, respectively.

In the structure using the dielectric layer and the metal fine patterned layer, as compared to a structure using a metal film, the external light reflectance (for wavelengths 550 nm and 650 nm) can be significantly reduced though the light extraction efficiency is reduced. In particular, the external light reflectance for the wavelength (650 nm) outside an emission band of the emission layer can be significantly reduced.

In this case, when the aperture ratio is adjusted so as to obtain constant light extraction efficiency, the external light reflectance is reduced by 0.84 times for the wavelength of 550 nm and 0.49 times for the wavelength of 650 nm. Further, if only the dielectric layer 105 is formed without providing the metal film or the metal fine patterned layer, light extraction efficiency is 10%. Therefore, the light extraction efficiency is reduced to decrease the luminance of the light emitting element.

As described above, with the structure of this example in which the dielectric layer and the metal fine patterned layer are provided, a light emitting element having low external light reflectance while maintaining high light extraction efficiency can be obtained.

### Example 2

As Example 2, a numerical example of Embodiment 2 is described. The graded-index diffraction element 103 is a diffraction grating in which titania portions, each of which is constituted of TiO₂ (refractive index: 2.0) with a diameter of 1,200 nm, are arranged in a silica layer, which is constituted of SiO₂ (refractive index: 1.46) with a thickness of 1,200 nm, in a triangular lattice at a cycle of 1,700 nm. In this case, light extraction efficiency is 47%, and external light reflectance for wavelengths of 550 nm and 650 nm is 70% and 39%, respectively.

On the other hand, in a structure using a metal film of Al, light extraction efficiency is 41%, and external light reflectance for wavelengths 550 nm and 650 nm is 93% and 89%, respectively.

According to the above-mentioned structure of the numerical example of Embodiment 2, back surface member reflectance of light entering at the critical angle θc or larger with a large solid angle is higher than that in the metal film. Therefore, the light extraction efficiency is increased as compared to the structure using the metal film.

As described above, with the structure of this example in which the dielectric layer and the metal fine patterned layer are provided, a light emitting element having low external light reflectance while maintaining high light extraction efficiency can be obtained.

### Example 3

As Example 3, a numerical example of Embodiment 3 is described. The emission layer 202 is formed of an organic material having a refractive index of 2.0, and emits light at a wavelength of 550 nm. Further, the dielectric layer 205 and the metal fine patterned layer 206 are provided in the stated order from the side opposite to the light extraction side. The dielectric layer 205 is constituted of SiO₂ (refractive index: 1.46) with a thickness of 450 nm. Further, the metal fine patterned layer 206 is such a structure as illustrated in FIG. 12 in which apertures 226, each of which is constituted of silver and is 90 nm on a side, are arranged in a film 216, which is formed of SiO₂ with a thickness of 90 nm, in a two-dimensional square lattice at a cycle of 320 nm.

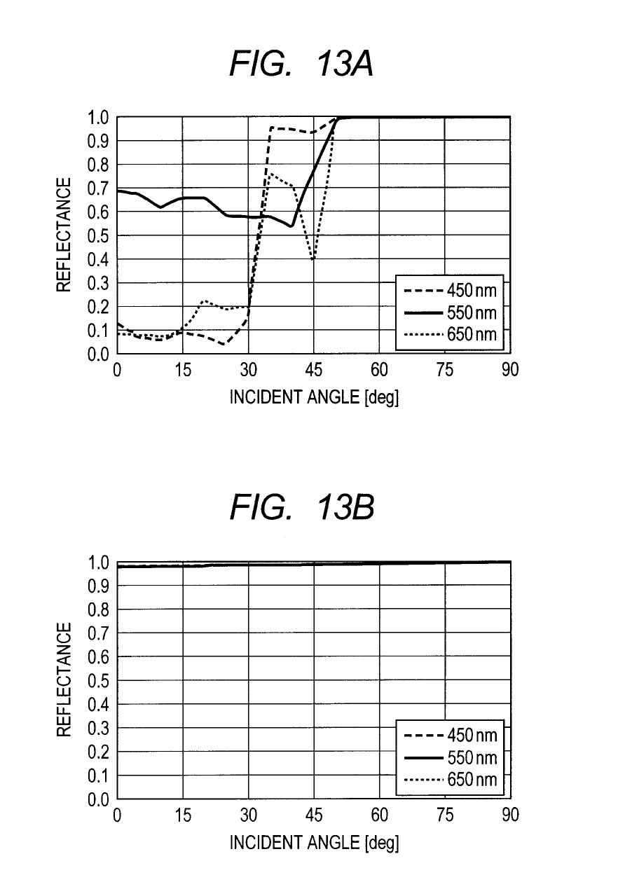

In this case, reflectance of light which is emitted from the emission layer 202 to the side opposite to the light extraction side and enters the dielectric layer 205 and the metal fine patterned layer 206 is illustrated in FIG. 13A. In this case, light extraction efficiency is 45%. Further, external light reflectance for wavelengths of 450 nm, 550 nm, and 650 nm is 8.4%, 64%, and 14%, respectively. Further, if silver is used as an electrode, the reflectance of the back surface member is measured as illustrated in FIG. 13B, which shows that light extraction efficiency is 51% and external light reflectance is 98% for each of the wavelengths of 450 nm, 550 nm, and 650 nm.

The external light reflectance can be reduced as compared to the light extraction efficiency which is reduced. In particular, the external light reflectance for the wavelength outside an emission band of the emission layer can be significantly reduced.

As described above, with the structure of this example in which the dielectric layer and the metal fine patterned layer are provided, a light emitting element having low external light reflectance while maintaining high light extraction efficiency can be obtained.

Note that, although in the structure of this example, SiO₂ is used to form the film, and silver as a metal is used to form the opening portion, the film may be a metal film formed of a metal such as silver, and the opening portion may be formed of a non-metal such as SiO₂, alternatively.

### Example 4

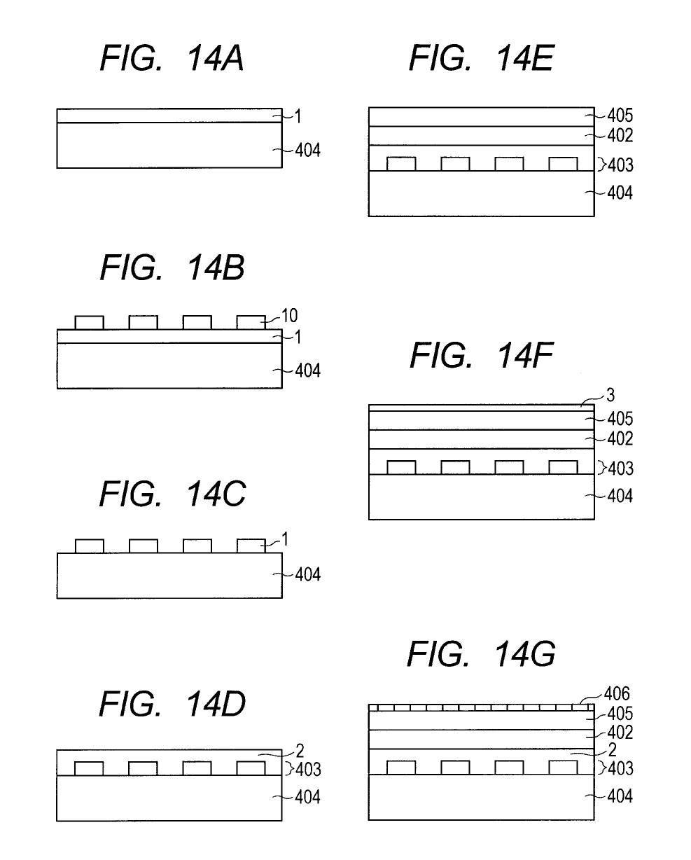

As Example 4, a manufacturing process for the light emitting element of each of Example 1, Example 2, and Example 3 is described with reference to FIGS. 14A to 14G.

In order to form a graded-index diffraction element 403 on a substrate 404, a material 1 for forming the graded-index diffraction element is laminated (FIG. 14A). Subsequently, a resist film is deposited by vapor deposition or sputtering and is exposed to light at predetermined positions to form a resist mask 10 (FIG. 14B). After that, using an etching technology such as reactive-ion etching (RIE), the material 1 is subjected to etching to a predetermined depth, and then the resist mask 10 is removed by ashing or the like (FIG. 14C). Next, a material is embedded into holes formed in the material 1, to thereby form the graded-index diffraction element 403 (FIG. 14D). Further, an electrode such as indium tin oxide (ITO) is formed by vapor deposition or sputtering as necessary. After that, an emission layer 402 is formed, and a dielectric layer 405 is formed (FIG. 14E).

Next, in order to form a metal fine patterned layer 406, a metal 3 is deposited by vapor deposition or sputtering (FIG. 14F). Subsequently, a resist mask is formed and exposed to light at predetermined positions, followed by etching, ashing, and the like, to thereby form the metal fine patterned layer 406 (FIG. 14G). After that, if necessary, a dielectric body, an electrode, and the like are laminated.

Note that, this example has exemplified the light emitting element of a bottom emission type, in which the substrate 404 side is the light extraction side. However, this example is not limited to the light emitting element of the bottom emission type. A light emitting element of a top emission type can also be manufactured by a similar manufacturing method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-17780, filed Aug. 6, 2010, which is hereby incorporated by reference herein in its entirety.

What is claimed is:

1. A light emitting element having a structure in which an emission layer is excited to emit light by an excitation source and the light is extracted from the emission layer to an outside,
the light emitting element comprising a back surface member, which is provided on a side of the emission layer opposite to a light extraction side,
wherein the back surface member comprises in order from the emission layer side:
a dielectric layer which has a smaller effective refractive index than an effective refractive index of the emission layer; and
a metal fine patterned layer which interacts with light that is emitted from the emission layer to enter the metal fine patterned layer via the dielectric layer, to thereby change level of reflectance according to a wavelength of the light, and
wherein, when a critical angle determined by conditions for total reflection at an interface between the emission layer and the dielectric layer is expressed by the following expression (1), a back surface member reflectance with respect to light with an incident angle larger than the critical angle is higher than a back surface member reflectance with respect to light with an incident angle smaller than the critical angle.
$$θ c = arc sin [ \frac{N 2}{N 1} ] \qquad ( Expression 1 )$$
where the effective refractive index means an average refractive index in each of the emission layer and the dielectric layer, θc represents the critical angle, N1 represents the effective refractive index of the emission layer, and N2 represents the effective refractive index of the dielectric layer.

2. The light emitting element according to claim 1,
wherein the dielectric layer is structured to have a smaller effective refractive index than the effective refractive index of the emission layer so that the light entering the dielectric layer at the critical angle or larger is totally reflected while the light entering the dielectric layer at the angle smaller than the critical angle is transmitted, and
wherein the metal fine patterned layer interacts with the light entering the dielectric layer at the angle smaller than the critical angle to be transmitted through the dielectric layer.

3. The light emitting element according to claim 2, wherein the reflectance obtained by the interaction with the metal fine patterned layer is high with respect to light at a center wavelength of an emission band of the light emitted from the emission layer and transmitted through the dielectric layer, and lower with respect to light at a wavelength different from the center wavelength than the reflectance with respect to the light at the center wavelength.

4. The light emitting element according to claim 3, wherein the reflectance with respect to the light at the center wavelength of the emission band is higher than reflectance with respect to light at a wavelength other than the emission band.

5. The light emitting element according to claim 1, wherein the metal fine patterned layer comprises metal structures which are regularly arranged on a side of the dielectric layer opposite to the light extraction side.

6. The light emitting element according to claim 1, wherein the metal fine patterned layer comprises a metal layer including apertures which are regularly provided on a side of the dielectric layer opposite to the light extraction side.

7. The light emitting element according to claim 1, wherein the metal fine patterned layer serves also as an electrode to be applied with an external voltage.

8. The light emitting element according to claim 1, wherein the dielectric layer has a thickness larger than a value obtained by dividing a wavelength of the light emitted from the emission layer by the effective refractive index of the dielectric layer.

9. The light emitting element according to claim 1, further comprising a graded-index diffraction element, which is provided on the light extraction side of the emission layer.

10. The light emitting element according to claim 1, wherein the critical angle is smaller than 60 degrees.

11. The light emitting element according to claim 1, wherein a difference between the critical angle and a maximum refraction angle θ1 expressed by the following expression (2) is smaller than 30 degrees.
$$θ 1 = arc sin [ \frac{1}{N 1} ] . \qquad ( Expression 2 )$$

12. The light emitting element according to claim 1,
wherein the excitation source comprises electrons emitted from an electron source, and
wherein the electrons emitted from the electron source are radiated to the emission layer from the side opposite to the light extraction side.

13. The light emitting element according to claim 1,
wherein the excitation source comprises a current to be injected, and
wherein the emission layer is formed of an organic material.
